(19) United States
(12) Patent Application Publication
(10) Pub. No.: US 2015/0311043 A1
(43) Pub. Date: Oct. 29, 2015

(54) CHAMBER COMPONENT WITH FLUORINATED THIN FILM COATING

(71) Applicant: Applied Materials, Inc., Santa Clara, CA (US)

(72) Inventors: Jennifer Y. Sun, Mountain View, CA (US); Vahid Firouzdor, San Mateo, CA (US); Biraja P. Kanungo, San Jose, CA (US); Dmitry Lubomirsky, Cupertino, CA (US); Sung Je Kim, Santa Clara, CA (US)

(21) Appl. No.: 14/696,085

(22) Filed: Apr. 24, 2015

Related U.S. Application Data
(60) Provisional application No. 61/984,668, filed on Apr. 25, 2014.

(51) Int. Cl. H01J 37/32; C23C 14/22; C23C 14/46; C23C 4/12

(52) U.S. Cl. CPC H01J 37/32798; C23C 4/12; C23C 14/221; C23C 14/46; H01J 2237/0203

(57) ABSTRACT

A chamber component comprises a body and a fluorinated thin film protective layer over at least one surface of the body. The fluorinated thin film protective layer does not react with process gasses having Fluorine based chemistry. The fluorinated thin film protective layer may be a YF₃ layer.

### RELATED APPLICATIONS

This patent application claims the benefit under 35 U.S.C. §119(e) of U.S. Provisional Application No. 61/984,668, filed Apr. 25, 2014.

### TECHNICAL FIELD

Embodiments of the present invention relate, in general, to chamber components having a Fluorine based thin film plasma resistant protective layer.

### BACKGROUND

In the semiconductor industry, devices are fabricated by a number of manufacturing processes producing structures of an ever-decreasing size. Some manufacturing processes such as plasma etch and plasma clean processes expose a substrate to a high-speed stream of plasma to etch or clean the substrate. The plasma may be highly corrosive, and may corrode processing chambers and other surfaces that are exposed to the plasma.

To minimize the effects of corrosive plasma, chamber components may be coated with plasma resistant spray coatings. However, such coatings may react with a Fluorine based plasma, which can affect process performance.

### SUMMARY

In an example embodiment a chamber component of an etch reactor includes a body and a fluorinated thin film protective layer over at least one surface of the body, wherein the fluorinated thin film protective layer does not react with process gasses having a Fluorine based chemistry.

In another example embodiment, a method includes providing a chamber component of an etch reactor and performing ion assisted deposition (IAD) to deposit a fluorinated thin film protective layer on at least one surface of the chamber component, wherein the fluorinated thin film protective layer does not react with process gasses having a Fluorine based chemistry.

In another example embodiment, a chamber component for a processing chamber is prepared by a process that includes performing ion assisted deposition (IAD) to deposit a fluorinated thin film protective layer on at least one surface of the chamber component, the fluorinated thin film protective layer thin film having a thickness of less than approximately 50 microns and comprising YF₃.

### BRIEF DESCRIPTION OF THE DRAWINGS

Embodiments of the present invention are illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 depicts a sectional view of one embodiment of a processing chamber.

FIGS. 2-3 depict cross sectional side views of example articles with thin film protective layers on one surface.

FIG. 4 illustrates one embodiment of a process for forming one or more protective layers over an article.

FIG. 5A depicts a deposition mechanism applicable to a variety of deposition techniques utilizing energetic particles such as ion assisted deposition (IAD).

FIG. 5B depicts a schematic of an IAD deposition apparatus.

FIG. 6 illustrates erosion rates for Y₂O₃ and for a YF₃ thin film protective layer formed in accordance with embodiments of the present invention.

FIG. 7 illustrates an x-ray diffraction reading of a YF₃ thin film protective layer over an aluminum substrate, in accordance with one embodiment of the present invention.

### DETAILED DESCRIPTION OF EMBODIMENTS

Embodiments of the present invention provide an article such as a showerhead or other chamber component for a processing chamber having a fluorinated thin film protective layer on one or more surfaces of the article. The fluorinated thin film protective layer may have a thickness below approximately 200 microns, and may provide plasma corrosion resistance for protection of the article. Additionally, the fluorinated thin film protective layer may not be reactive to Fluorine based chemistries. The fluorinated thin film protective layer may be formed on the article using ion assisted deposition (IAD) or physical vapor deposition (PVD). The fluorinated thin film protective layer may be used as a top coat over a thick film protective layer, which may have been formed using, for example, plasma spraying techniques. Alternatively, the protective layer may be formed over a bare article. The fluorinated thin film protective layer may be YF₃. The improved erosion resistance provided by the fluorinated thin film protective layer may improve the service life of the article, while reducing maintenance and manufacturing cost. Additionally, the fluorinated thin film protective layer does not cause a shift in process results of processes using Fluorine based chemistries (e.g., of NF₃).

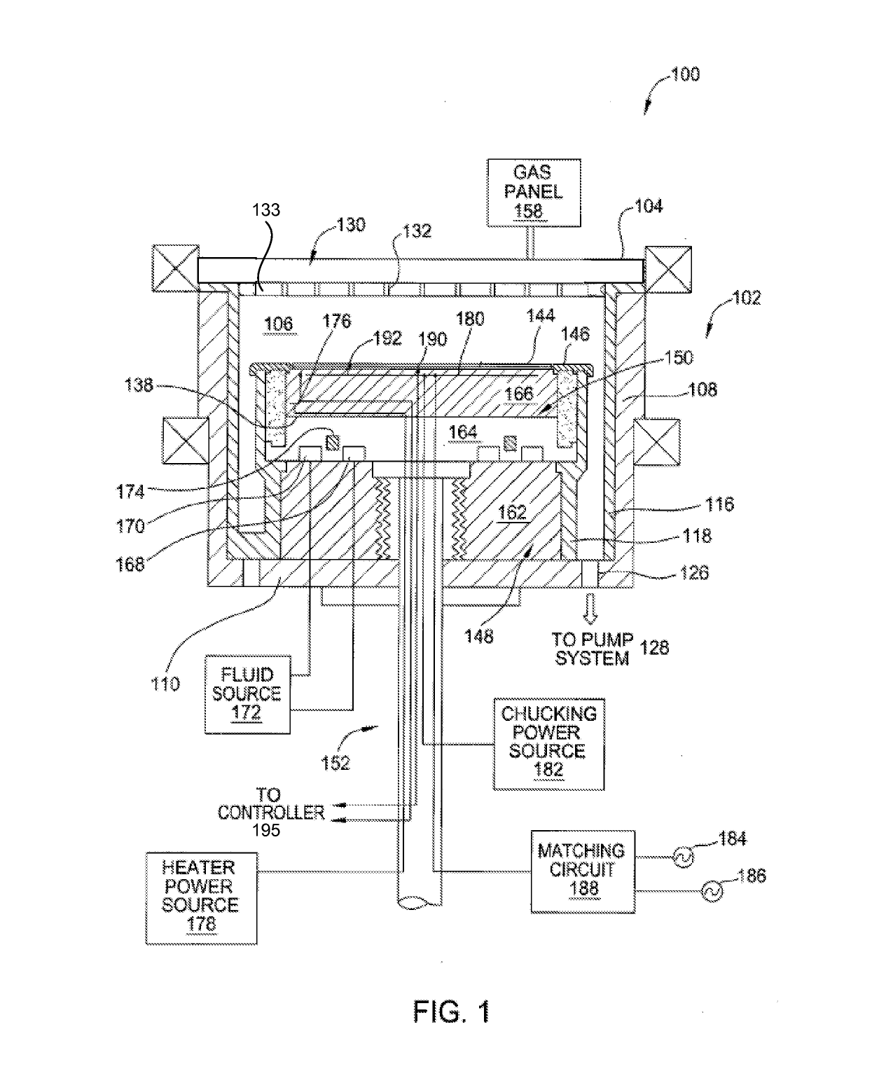

FIG. 1 is a sectional view of a semiconductor processing chamber 100 having one or more chamber components that are coated with a fluorinated thin film protective layer in accordance with embodiments of the present invention. The processing chamber 100 may be used for processes in which a Fluorine based corrosive plasma environment is provided. For example, the processing chamber 100 may be a chamber for a plasma etcher or plasma etch reactor, a plasma cleaner, and so forth that uses a Fluorine based chemistry for etching and/or cleaning. Examples of chamber components that may include a fluorinated thin film protective layer include a substrate support assembly 148, an electrostatic chuck (ESC) 150, a ring (e.g., a process kit ring or single ring), a chamber wall, a base, a gas distribution plate, a showerhead, a liner, a liner kit, a shield, a plasma screen, a flow equalizer, a cooling base, a chamber viewport, a chamber lid, a face plate, an selectivity modulation device (SMD), and so on. The fluorinated thin film protective layer, which is described in greater detail below, may include YF₃ (yttrium fluoride).

In one embodiment, the processing chamber 100 includes a chamber body 102 and a showerhead 130 that enclose an interior volume 106. Alternatively, the showerhead 130 may be replaced by a lid and a nozzle in some embodiments. The chamber body 102 may be fabricated from aluminum, stainless steel or other suitable material. The chamber body 102 generally includes sidewalls 108 and a bottom 110. Any of the showerhead 130 (or lid and/or nozzle), sidewalls 108 and/or bottom 110 may include a fluorinated thin film protective layer.

An outer liner 116 may be disposed adjacent the sidewalls 108 to protect the chamber body 102. The outer liner 116 may be fabricated and/or coated with a fluorinated thin film protective layer. In one embodiment, the outer liner 116 is fabricated from aluminum oxide.

An exhaust port 126 may be defined in the chamber body 102, and may couple the interior volume 106 to a pump system 128. The pump system 128 may include one or more pumps and throttle valves utilized to evacuate and regulate the pressure of the interior volume 106 of the processing chamber 100.

The showerhead 130 may be supported on the sidewall 108 of the chamber body 102. The showerhead 130 (or lid) may be opened to allow access to the interior volume 106 of the processing chamber 100, and may provide a seal for the processing chamber 100 while closed. A gas panel 158 may be coupled to the processing chamber 100 to provide process and/or cleaning gases to the interior volume 106 through the showerhead 130 or lid and nozzle. Showerhead 130 is used for processing chambers used for dielectric etch (etching of dielectric materials). The showerhead 130 includes a gas distribution plate (GDP) 133 having multiple gas delivery holes 132 throughout the GDP 133. The showerhead 130 may include the GDP 133 bonded to a showerhead base 104, which may be an aluminum base or an anodized aluminum base. The GDP 133 may be made from Si or SiC, or may be a ceramic such as Y₂O₃, Al₂O₃, Y₃Al₅O₁₂ (YAG), and so forth.

For processing chambers used for conductor etch (etching of conductive materials), a lid may be used rather than a showerhead. The lid may include a center nozzle that fits into a center hole of the lid. The lid may be a ceramic such as Al₂O₃, Y₂O₃, YAG, or a ceramic compound comprising Y₄Al₂O₉ and a solid-solution of Y₂O₃—ZrO₂. The nozzle may also be a ceramic, such as Y₂O₃, YAG, or the ceramic compound comprising Y₄Al₂O₉ and a solid-solution of Y₂O₃—ZrO₂. The lid, showerhead base 104, GDP 133 and/or nozzle may be coated with a fluorinated thin film protective layer.

Examples of Fluorine based processing gases that may be used to process substrates in the processing chamber 100 include halogen-containing gases, such as C₂F₆, SF₆, NF₃, CF₄, CHF₃, CH₂F₃, F, NF₃, and SiF₄, among others. Examples of carrier gases that may also be used include N₂, He, Ar, and other gases inert to process gases (e.g., non-reactive gases).

In some embodiments, the processing chamber 100 may include a face plate and/or a selectivity modulation device (SMD) that may be positioned above the showerhead. The face plate and SMD are components used for providing remote plasma to the processing chamber 100. The face plate and SMD may be made out of Aluminum (e.g., Aluminum 6061) or another metal. In some instances, the face plate and SMD have a plasma sprayed protective coating such as a coating of Y₂O₃ for erosion protection. These components may be used, for example, if the processing chamber is a remote plasma chamber (e.g., a selective removal products (SRP) chamber). In operation, there is a low intensity plasma between the face plate and SMD, and a radical will go through them to the wafer for selective etching. The SMD modulates selectivity of the plasma.

The substrate support assembly 148 is disposed in the interior volume 106 of the processing chamber 100 below the showerhead 130 or lid. The substrate support assembly 148 holds the substrate 144 during processing. A ring 146 (e.g., a single ring) may cover a portion of the electrostatic chuck 150, and may protect the covered portion from exposure to plasma during processing. The ring 146 may be silicon or quartz in one embodiment.

An inner liner 118 may be coated on the periphery of the substrate support assembly 148. The inner liner 118 may be a halogen-containing gas resist material such as those discussed with reference to the outer liner 116. In one embodiment, the inner liner 118 may be fabricated from the same materials of the outer liner 116. Additionally, the inner liner 118 may be coated with a fluorinated thin film protective layer.

In one embodiment, the substrate support assembly 148 includes a mounting plate 162 supporting a pedestal 152, and an electrostatic chuck 150. The electrostatic chuck 150 further includes a thermally conductive base 164 and an electrostatic puck 166 bonded to the thermally conductive base by a bond 138, which may be a silicone bond in one embodiment. An upper surface of the electrostatic puck 166 may be covered by a fluorinated thin film protective layer. The mounting plate 162 is coupled to the bottom 110 of the chamber body 102 and includes passages for routing utilities (e.g., fluids, power lines, sensor leads, etc.) to the thermally conductive base 164 and the electrostatic puck 166.

The thermally conductive base 164 and/or electrostatic puck 166 may include one or more optional embedded heating elements 176, embedded thermal isolators 174 and/or conduits 168, 170 to control a lateral temperature profile of the substrate support assembly 148. The conduits 168, 170 may be fluidly coupled to a fluid source 172 that circulates a temperature regulating fluid through the conduits 168, 170. The embedded thermal isolator 174 may be disposed between the conduits 168, 170 in one embodiment. The heating element 176 is regulated by a heater power source 178. The conduits 168, 170 and heating element 176 may be utilized to control the temperature of the thermally conductive base 164, heating and/or cooling the electrostatic puck 166 and a substrate (e.g., a wafer) 144 being processed. The temperature of the electrostatic puck 166 and the thermally conductive base 164 may be monitored using a plurality of temperature sensors 190, 192, which may be monitored using a controller 195.

The electrostatic puck 166 may further include multiple gas passages such as grooves, mesas and other surface features, that may be formed in an upper surface of the electrostatic puck 166. The gas passages may be fluidly coupled to a source of a heat transfer (or backside) gas such as He via holes drilled in the electrostatic puck 166. In operation, the backside gas may be provided at controlled pressure into the gas passages to enhance the heat transfer between the electrostatic puck 166 and the substrate 144.

The electrostatic puck 166 includes at least one clamping electrode 180 controlled by a chucking power source 182. The electrode 180 (or other electrode disposed in the electrostatic puck 166 or conductive base 164) may further be coupled to one or more RF power sources 184, 186 through a matching circuit 188 for maintaining a Fluorine based plasma formed from process and/or other gases within the processing chamber 100. The RF power sources 184, 186 are generally capable of producing RF signal having a frequency from about 50 kHz to about 3 GHz and a power of up to about 10,000 Watts.

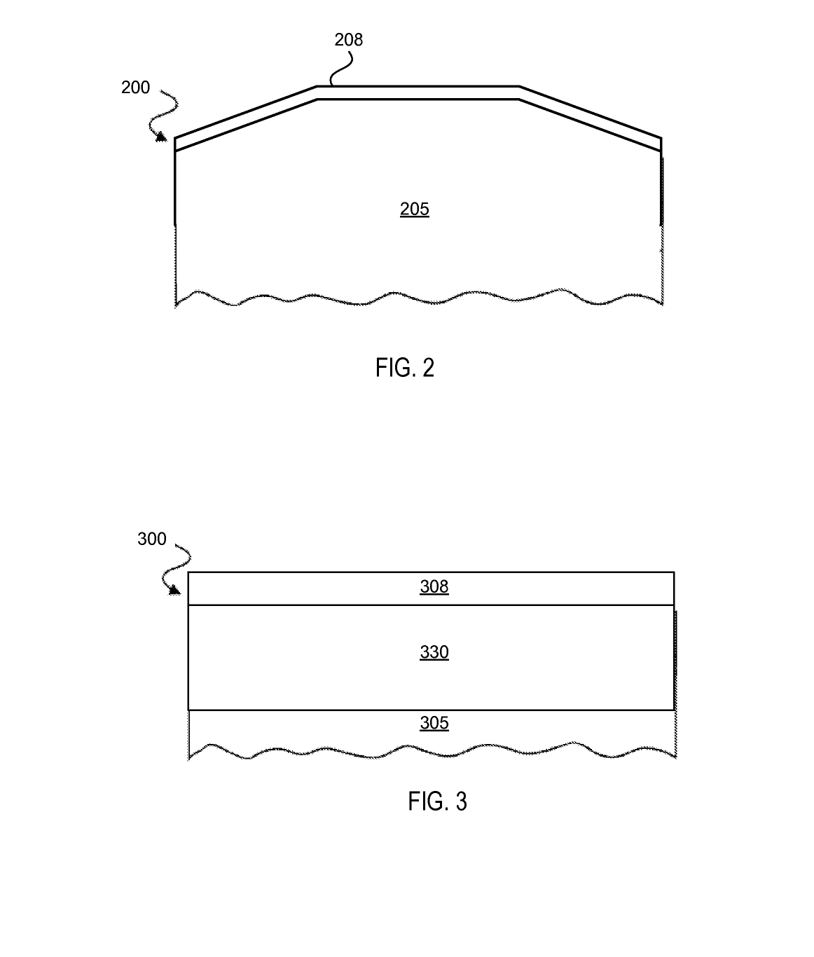

FIGS. 2-3 illustrate cross sectional side views of articles (e.g., chamber components) covered by fluorinated thin film protective layers. Referring to FIG. 2A, at least a portion of a base or body 205 of an article 200 is coated by a thin film protective layer 208. The article 200 may be a chamber component, such as a substrate support assembly, an electrostatic chuck (ESC), a ring (e.g., a process kit ring or single ring), a chamber wall, a base, a gas distribution plate or showerhead, a liner, a liner kit, a shield, a plasma screen, a flow equalizer, a cooling base, a chamber viewport, a chamber lid, a face plate, an SMD, and so on. The body 205 of the article 200 may be a metal, a ceramic, a metal-ceramic composite, a polymer, or a polymer-ceramic composite. In one embodiment, the body 205 of the article is an aluminum alloy (e.g., 6061 aluminum) or stainless steel. In another embodiment, the body 205 of the article is a ceramic material such as Al₂O₃, Y₂O₃, AlN, SiO₂, and so on. In another embodiment, the body 205 of the article is a polymer based material such as Kepton®, Teflon®, and so forth.

Various chamber components are composed of different materials. For example, an electrostatic chuck may be composed of a ceramic such as Al₂O₃ (alumina), AlN (aluminum nitride), TiO (titanium oxide), TiN (titanium nitride) or SiC (silicon carbide) bonded to an anodized aluminum base. Al₂O₃, AlN and anodized aluminum have poor plasma erosion resistance. When exposed to a plasma environment with a Fluorine chemistry, an electrostatic puck of an electrostatic chuck may exhibit degraded wafer chucking, increased He leakage rate, wafer front-side and back-side particle production and on-wafer metal contamination after about 50 radio frequency hours (RFHrs) of processing. A radio frequency hour is an hour of processing.

A lid for a plasma etcher used for conductor etch processes may be a sintered ceramic such as Al₂O₃ since Al₂O₃ has a high flexural strength and high thermal conductivity. However, Al₂O₃ exposed to Fluorine chemistries forms AlF particles as well as aluminum metal contamination on wafers.

The showerhead for an etcher used to perform dielectric etch processes is typically made of anodized aluminum bonded to a SiC faceplate. When such a showerhead is exposed to plasma chemistries including Fluorine, AlF may form due to plasma interaction with the anodized aluminum base. Additionally, a high erosion rate of the anodized aluminum base may lead to arcing and ultimately reduce a mean time between cleaning for the showerhead.

Some chamber lids and other chamber components have a thick film protective layer on a plasma facing side to minimize particle generation and metal contamination and to prolong the life of the lid. Plasma spraying and other thermal spraying techniques may be used to form the thick film protective layer. However, most thick film coating techniques have a long lead time. Additionally, for most thick film coating techniques special surface preparation is performed to prepare the article to be coated (e.g., the lid) to receive the coating. Such long lead times and coating preparation steps can increase cost and reduce productivity, as well as inhibit refurbishment. Additionally, most thick-film coatings have inherent cracks and pores that might degrade on-wafer defect performance.

One disadvantage of many thick film coatings such as a plasma sprayed Y₂O₃ is that these coatings will react with Fluorine based chemistries. For example, a Y₂O₃ (yttrium oxide) plasma sprayed protective coating may be used to protect a chamber component from erosion caused by Fluorine based chemistries. However, the Fluorine will react with the yttrium oxide to form yttrium fluoride at the surface of the plasma sprayed protective coating. In other words, the plasma sprayed protective coating will absorb some percentage of the Fluorine. The absorption of the Fluorine into the plasma sprayed protective coating reduces an amount of Fluorine that is available for an etch reaction. This may reduce an etch rate of an etch process. The fluoride may also later be sputtered from the protective coating, which can increase an amount of fluoride that is available for future etch processes. Accordingly, the stability of the etch rate for etch processes using Fluorine chemistries may be reduced.

The examples provided above set forth just a few chamber components whose performance may be improved by use of a fluorinated thin film protective layer as set forth in embodiments herein.

Referring back to FIG. 2, a body 205 of the article 200 may include one or more surface features, such as the mesa illustrated in FIG. 2A. For an electrostatic chuck, surface features may include mesas, sealing bands, gas channels, helium holes, and so forth. For a showerhead, surface features may include a bond line, hundreds or thousands of holes for gas distribution, divots or bumps around gas distribution holes, and so forth. Other chamber components may have other surface features.

The fluorinated thin film protective layer 208 formed on the body 205 may conform to the surface features of the body 205. As shown, the fluorinated thin film protective layer 208 maintains a relative shape of the upper surface of the body 205 (e.g., telegraphing the shapes of the mesa). Additionally, the fluorinated thin film coating may be thin enough so as not to plug holes in a showerhead or He holes in an electrostatic chuck. In one embodiment, the fluorinated thin film protective layer 208 has a thickness of below about 200 microns. In a further embodiment, the fluorinated thin film protective layer has a thickness of below 50 microns. In one embodiment, the fluorinated thin film protective layer has a thickness of 5-20 microns.

The fluorinated thin film protective layer 208 is a deposited ceramic layer that may be formed on the body 205 of the article 200 using an ion assisted deposition (IAD) process or a physical vapor deposition (PVD) process. The IAD or PVD deposited thin film protective layer 208 may have a relatively low film stress (e.g., as compared to a film stress caused by plasma spraying or sputtering). The IAD or PVD deposited thin film protective layer 208 may additionally have a porosity that is less than 1%, and less than about 0.1% in some embodiments. The IAD or PVD deposited protective layer is a dense structure, which can have performance benefits for application on a chamber component. Additionally, the fluorinated thin film protective layer 208 may be crack free upon deposition and after continued use.

The IAD or PVD deposited protective layer 208 may be deposited without first roughening the upper surface of the body 205 or performing other time consuming surface preparation steps. Since roughening the body may reduce a breakdown voltage of the body 205, the ability to apply the fluorinated thin film protective layer 208 without first roughening the body 205 may be beneficial for some applications (e.g., for an electrostatic chuck). Moreover, the fluorinated thin film protective layer 208 is very smooth and reduces both particle defects and metal contamination for processed wafers.

The fluorinated thin film protective layer 208 does not react with Fluorine based chemistries. Accordingly, the Fluorine concentration in Fluorine based plasmas may remain constant during etch and clean processes. As a result, the etch rate also remains steady during the etch and clean processes.

In one embodiment, the fluorinated thin film protective layer 208 is composed of YF₃. Alternatively, other fluorinated ceramic materials that are resistant to plasma erosion from Fluorine based chemistries may be used. The fluorinated thin film protective layer 208 may additionally include trace amounts of other materials such as ZrO₂, Al₂O₃, SiO₂, B₂O₃, Er₂O₃, Nd₂O₃, Nb₂O₅, CeO₂, Sm₂O₃, Yb₂O₃, or other oxides.

TABLE 1
Material properties for IAD deposited YF₃.

| Property | 92% Al₂O₃ | YF₃ |
|---|---|---|
| Crystal Structure | C | A |
| Breakdown Voltage (V) | 363 | 522 (5 μm coating) |
| Roughness (μin) | 8 | Unchanged |
| Hermicity (leak rate) (cm³/s) | <1E−6 | 2.6E−9 |
| Hardness (GPa) | 12.14 | 3.411 |

Table 1 shows material properties for a substrate of 92% Al₂O₃ (alumina) and for a YF₃ thin film protective layer coating a substrate of 92% Al₂O₃. As shown, the alumina substrate has a breakdown voltage of 363 Volts/mil (V/mil). In contrast, a 5 micron (μm) coating of the IAD deposited YF₃ has a breakdown voltage of 522 V (much more than the normalized value of 363 Volts/mil for alumina).

The alumina substrate may have a starting roughness of approximately 8 microinches in one embodiment, and that starting roughness may be approximately unchanged in the YF₃ thin film protective layer. Features such as holes in a showerhead may not be plugged by the thin film protective layer.

Hermicity measures the sealing capacity that can be achieved using the thin film protective layer. As shown, a He leak rate of around 1E-6 cubic centimeters per second (cm³/s) can be achieved using alumina, and a He leak rate of around 2.6E-9 can be achieved using YF₃. Lower He leak rates indicate an improved seal. The example YF₃ thin film protective layer has a lower He leak rate than typical Al₂O₃.

Alumina has a Vickers hardness (5 Kgf) of around 12.14 Giga Pascals (GPa), and YF₃ has a hardness of around 3.411 GPa.

Note that the deposition parameters for the YF₃ thin may be modified such that the material properties and characteristics identified above may vary by up to 30% in some embodiments. Accordingly, the described values for these material properties should be understood as example achievable values. The ceramic thin film protective layers described herein should not be interpreted as being limited to the provided values.

FIG. 3 illustrates a cross sectional side view of one embodiment of an article 300 having a thick protective layer 330 and a fluorinated thin film protective layer 308. The thick protective layer may be Y₃Al₅O₁₂, Y₄Al₂O₉, Y₂O₃, or a ceramic compound comprising Y₄Al₂O₉ and a solid-solution of Y₂O₃—ZrO₂. In one embodiment, the ceramic compound can include Y₂O₃ in a range of 50-75 mol %, ZrO₂ in a range of 10-30 mol % and Al₂O₃ in a range of 10-30 mol %. Other plasma resistant ceramics may also be used for the thick protective layer 330.

The thick protective layer 330 may be a thick film protective layer, which may have been thermally sprayed (e.g., plasma sprayed) onto the body 305. An upper surface of the body 305 may be roughened prior to plasma spraying the thick film protective layer onto it. The roughening may be performed, for example, by bead blasting the body 305. Roughening the upper surface of the body provides anchor points to create a mechanical bond between the plasma sprayed thick film protective layer and the body 305 for better adhesion. The thick film protective layer may have an as sprayed thickness of up to about 200 microns or thicker, and may be ground down to a final thickness of approximately 50 microns in some embodiments. In one embodiment, the thick protective layer has a thickness of over 100 microns (μm). A plasma sprayed thick film protective layer may have a porosity of about 2-4%.

Alternatively, the thick protective layer 330 may be a bulk sintered ceramic that has been bonded to the body 305. The thick protective layer 330 may be provided, for example, as a thin ceramic wafer having a thickness of approximately 200 microns.

The fluorinated thin film protective layer 308 may be applied over the thick protective layer 330 using IAD or PVD. The fluorinated thin film protective layer 308 may act as a top coat, and may act as an erosion resistant barrier and seal an exposed surface of the thick protective layer 330 (e.g., seal inherent surface cracks and pores in the thick protective layer 330).

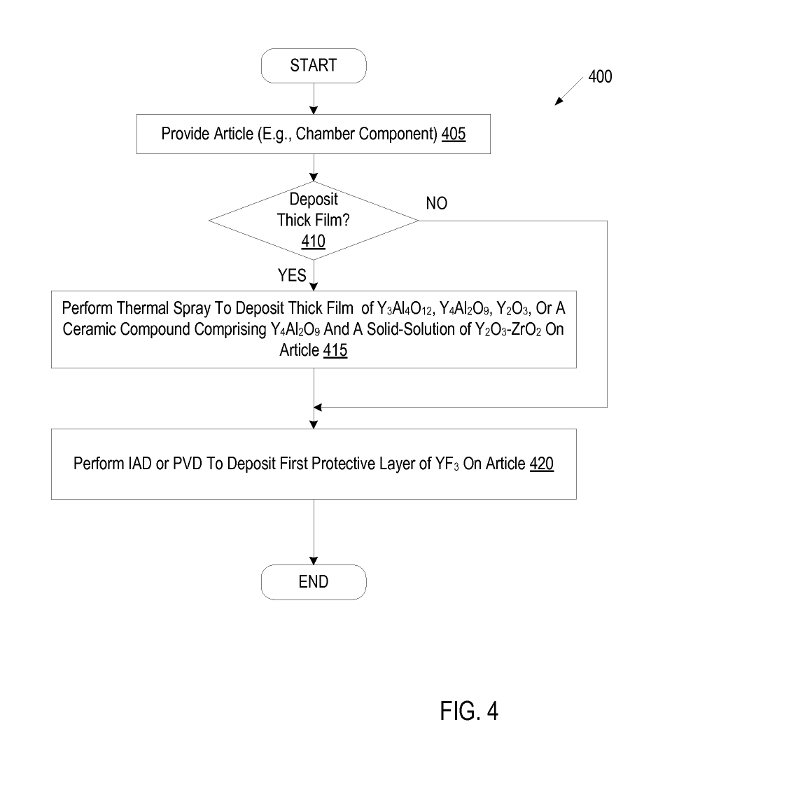

FIG. 4 illustrates one embodiment of a process 400 for forming a fluorinated thin film protective layer over a body of an article such as a showerhead or other chamber component for an etch reactor. At block 405 of process 400, an article is provided. At block 410, a determination is made of whether or not to deposit a thick film protective layer onto the article. If a thick film protective layer is to be formed, the method proceeds to block 415. Otherwise, the method continues to block 420.

At block 415, a thermal spray process (e.g., a plasma spray process) is performed to deposit a thick film protective layer onto the article. Prior to performing the thermal spray process, the body of the article may be roughened in some embodiments. The thick film protective layer may be any plasma resistant ceramic. Some examples of thick film protective layers include Y₃Al₆O₁₂, Y₄Al₂O₉, Y₂O₃, YSZ, or the ceramic compound comprising Y₄Al₂O₉ and a solid-solution of Y₂O₃—ZrO₂. After the thick film protective layer is formed, for some applications surface features are formed on a surface of the thick film protective layer. For example, if the article is an ESC, then mesas and He holes may be formed. In an alternative embodiment, a plasma resistant ceramic disc or other ceramic structure may be bonded to the body of the article rather than spraying a thick film protective layer.

At block 420, IAD or PVD is performed to deposit a fluorinated thin film protective layer on the body of the article. If a thick film protective layer was formed at block 415, then the fluorinated thin film protective layer may be formed over the thick film protective layer as a top coat. In one embodiment, chamber surface preparation is performed prior to performing IAD to deposit the fluorinated thin film protective layer. For example, ion guns can prepare a surface of the article by using Oxygen and/or Argon ions to burn surface organic contamination and disperse remaining surface particles.

The fluorinated thin film protective layer may be YF₃. A deposition rate for the thin film protective layer may be about 0.25-10 Angstroms per second (A/s), and may be varied by tuning deposition parameters. In one embodiment, multiple deposition rates are used during deposition of the fluorinated thin film protective layer. For example, an initial deposition rate of 0.25-1.0 A/s may be used to achieve a conforming and well adhering coating. The deposition rate may then be increased to 2-10 A/s to achieve a thicker coating in a shorter and more cost effective coating run. The thin film protective layers may be very conforming, may be uniform in thickness, and have a good adhesion to the body/substrate that they are deposited on.

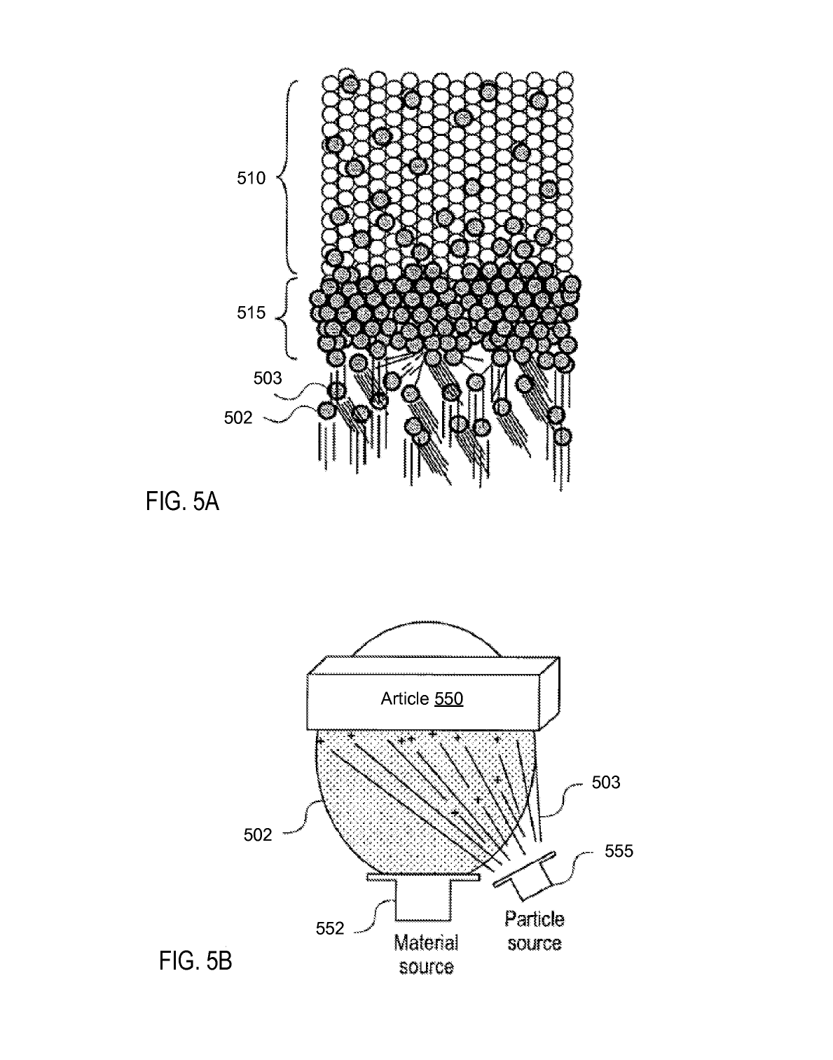

FIG. 5A depicts a deposition mechanism applicable to a variety of deposition techniques utilizing energetic particles such as ion assisted deposition (IAD). Exemplary IAD methods include deposition processes which incorporate ion bombardment, such as evaporation (e.g., activated reactive evaporation (ARE) or electron beam ion assisted deposition (EB-IAD)) and sputtering (e.g., ion beam sputtering ion assisted deposition (IBS-IAD)) in the presence of ion bombardment to form plasma resistant coatings as described herein. EB-IAD may be performed by evaporation. IBS-IAD may be performed by sputtering a solid target material (e.g., a solid metal target). Any of the IAD methods may be performed in the presence of a reactive gas species, such as O₂, N₂, halogens, etc.

As shown, the thin film protective layer 515 is formed by an accumulation of deposition materials 502 in the presence of energetic particles 503 such as ions. The deposition materials 502 include atoms, ions, radicals, or their mixture. The energetic particles 503 may impinge and compact the thin film protective layer 515 as it is formed.

In one embodiment, IAD is utilized to form the fluorinated thin film protective layer 515, as previously described elsewhere herein. FIG. 5B depicts a schematic of an IAD deposition apparatus. As shown, a material source 552 provides a flux of deposition materials 502 while an energetic particle source 555 provides a flux of the energetic particles 503, both of which impinge upon the article 550 throughout the IAD process. The energetic particle source 555 may be an Oxygen or other ion source. The energetic particle source 555 may also provide other types of energetic particles such as inert radicals, neutron atoms, and nano-sized particles which come from particle generation sources (e.g., from plasma, reactive gases or from the material source that provide the deposition materials). The material source (e.g., a target body) 552 used to provide the deposition materials 502 may be a bulk sintered ceramic corresponding to the same ceramic that the thin film protective layer 515 is to be composed of. For example, the material source may be a bulk sintered YF₃.

IAD may utilize one or more plasmas or beams to provide the material and energetic ion sources. Reactive species may also be provided during deposition of the plasma resistant coating. In one embodiment, the energetic particles 503 include at least one of non-reactive species (e.g., Ar) or reactive species (e.g., O). In further embodiments, reactive species such as CO and halogens (Cl, F, Br, etc.) may also be introduced during the formation of a plasma resistant coating to further increase the tendency to selectively remove deposited material most weakly bonded to the thin film protective layer 515.

With IAD processes, the energetic particles 503 may be controlled by the energetic ion (or other particle) source 555 independently of other deposition parameters. According to the energy (e.g., velocity), density and incident angle of the energetic ion flux, composition, structure, crystalline orientation and grain size of the thin film protective layer may be manipulated. Additional parameters that may be adjusted are a temperature of the article during deposition as well as the duration of the deposition.

The ion assist energy is used to densify the coating and to accelerate the deposition of the material on the surface of the substrate. Ion assist energy can be varied using both the voltage and current of the ion source. The voltage and current can be adjusted to achieve high and low coating density, to manipulate a stress of the coating and also a crystallinity of the coating. The ion assist energy may range from approximately 50-500 V and approximately 1-50 amps (A). The ion assist energy can also be used to intentionally change a stoichiometry of the coating. For example, a metallic target can be used during deposition, and converted to a metal oxide.

Coating temperature can be controlled by using heaters to heat a deposition chamber and/or a substrate and by adjusting a deposition rate. Substrate (article) temperature during deposition may be roughly divided into low temperature (around 120-150° C. in one embodiment which is typical room temperature) and high temperature (around 270° C. or above in one embodiment). Deposition temperature can be used to adjust film stress, crystallinity, and other coating properties.

A working distance is a distance between the electron beam (or ion beam) gun and the substrate. The working distance can be varied to achieve a coating with a highest uniformity. Additionally, working distance may affect deposition rate and density of the coating.

A deposition angle is the angle between the electron beam (or ion beam) and the substrate. Deposition angle can be varied by changing the location and/or orientation of the substrate. By optimizing the deposition angle, a uniform coating in three dimensional geometries can be achieved.

EB-IAD and IBS-IAD depositions are feasible on a wide range of surface conditions. However, polished surfaces are preferred to achieve a uniform coating coverage. Various fixtures may be used to hold the substrate during the IAD deposition.

TABLE 2
Example Fluorinated Thin Film Protective
Layer Formed Using IAD

| | Thick- | | | | | Vacuum | Hard- |
|---|---|---|---|---|---|---|---|
| Mate- | ness | Dep. Rate | Ion | Temp. | | Sealing | ness |
| rial | (μm) | (A/s) | Assist | (° C.) | XRD | (cm³/s) | (GPa) |
| YF₃ | 5 | 1 for 1 μm | 270 V, | 120-150 | A | 2.6E−9 | 3.411 |
| | | 2 for 4 μm | 7 A | | | | |

Table 2 shows an example YF₃ thin film protective layer formed using IAD. The example YF₃ thin film protective layer has a thickness of 5 microns, and was formed using IAD with a high energy ion assist, a temperature of 120-150° C., and a deposition rate of 1 A/s for the first micron and a deposition rate of 2 A/s for the subsequent microns. X-ray diffraction showed that the YF₃ ceramic thin film protective layer had an amorphous structure. When used as a seal, the YF₃ ceramic thin film protective layer was able to maintain a vacuum down to 2.6E-9 cm³/s. The YF₃ ceramic thin film protective layer had a hardness of 3.411 GPa.

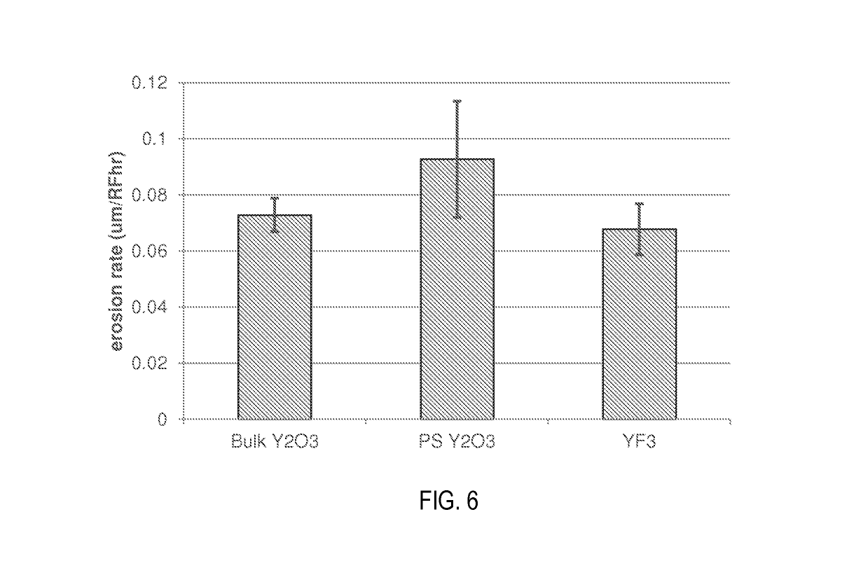

FIG. 6 illustrates erosion rates for Y₂O₃ and for a YF₃ thin film protective layer when exposed to Fluorine based plasmas, in accordance with embodiments of the present invention. As shown, the IAD deposited YF₃ thin film protective layer shows an improved erosion resistance as compared to both bulk sintered Y₂O₃ and plasma sprayed (PS) Y₂O₃. In particular, bulk Y₂O₃ has an erosion rate of approximately 0.07 μm/RFhr, plasma sprayed Y₂O₃ has an erosion rate of approximately 0.09 μm/RFhr, and the IAD deposited YF₃ thin film protective layer has an erosion rate of less than 0.07 μm/RFhr.

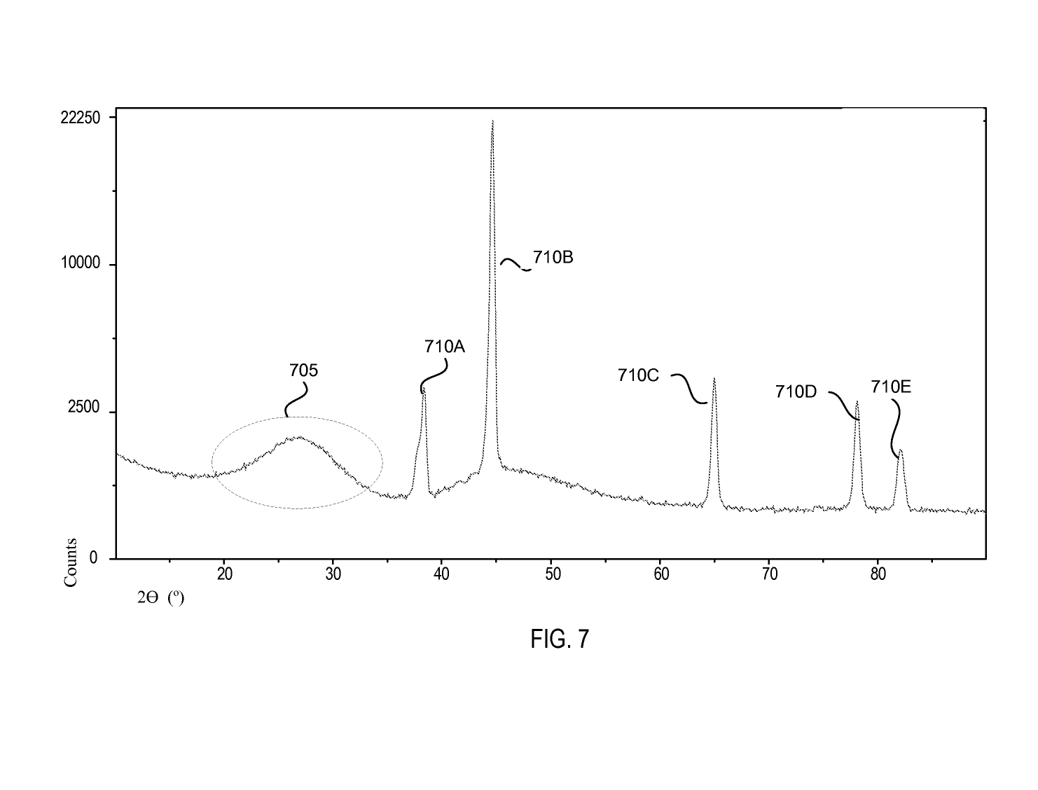

FIG. 7 illustrates an x-ray diffraction (XRD) reading of a YF₃ thin film protective layer over an aluminum alloy substrate (e.g., aluminum 6061), in accordance with one embodiment of the present invention. A vertical axis represents intensity based on counts per second, and the horizontal axis represents a 20 scale in degrees (°). The XRD reading shows a gradual peak 705 for YF3, indicating that the YF₃ is amorphous. The XRD reading additionally shows multiple peaks 710A-710E for Aluminum 6061.

The preceding description sets forth numerous specific details such as examples of specific systems, components, methods, and so forth, in order to provide a thorough understanding of several embodiments of the present invention. It will be apparent to one skilled in the art, however, that at least some embodiments of the present invention may be practiced without these specific details. In other instances, well-known components or methods are not described in detail or are presented in simple block diagram format in order to avoid unnecessarily obscuring the present invention. Thus, the specific details set forth are merely exemplary. Particular implementations may vary from these exemplary details and still be contemplated to be within the scope of the present invention.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±30%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the invention should, therefore, be determined with reference to the appended claims, along with the full scope of equivalents to which such claims are entitled.

What is claimed is:

1. A chamber component of an etch reactor comprising:
a body; and
a fluorinated thin film protective layer over at least one surface of the body, wherein the fluorinated thin film protective layer does not react with process gasses having a Fluorine based chemistry.

2. The chamber component of claim 1, wherein the body comprises a metal.

3. The chamber component of claim 1, wherein the fluorinated thin film protective layer is conformal and has a thickness of less than 50 microns.

4. The chamber component of claim 1, wherein the body comprises at least one of a ceramic, a glass or a polymer.

5. The chamber component of claim 1, wherein the chamber component comprises a showerhead, a selectivity modulation device or a face plate.

6. The chamber component of claim 1, wherein the fluorinated thin film protective layer comprises YF₃.

7. The chamber component of claim 1, further comprising:
a plasma sprayed protective layer on the surface of the body, wherein the fluorinated thin film protective layer is disposed on the plasma sprayed protective layer.

8. The chamber component of claim 7, wherein the plasma sprayed protective layer comprises Y₂O₃.

9. The chamber component of claim 1, wherein the fluorinated thin film protective layer comprises an ion assisted deposition (IAD) deposited layer.

10. The chamber component of claim 1, wherein the fluorinated thin film protective layer is an amorphous layer.

11. The chamber component of claim 1, wherein the fluorinated thin film protective layer has an erosion rate of less than 0.07 μm per hour when exposed to a Fluorine based plasma.

12. A method comprising:
providing a chamber component; and
performing ion assisted deposition (IAD) to deposit a fluorinated thin film protective layer on at least one surface of the chamber component, wherein the fluorinated thin film protective layer does not react with process gasses having a Fluorine based chemistry.

13. The method of claim 12, wherein the chamber component comprises a metallic substrate.

14. The method of claim 12, wherein the fluorinated thin film protective layer is conformal and has a thickness of less than 50 microns.

15. The method of claim 12, wherein the chamber component comprises a selectivity modulation device, a face plate, a showerhead base or a showerhead gas distribution plate (GDP).

16. The method of claim 12, wherein the fluorinated thin film protective layer comprises YF₃.

17. The method of claim 12, further comprising:
prior to depositing the fluorinated thin film protective layer on the at least one surface of the chamber component, performing a thermal spraying process to deposit an additional protective layer on the at least one surface of the body, wherein the additional protective layer is a thick film having a thickness of greater than approximately 100 microns.

18. The method of claim 17, wherein the additional protective layer comprises a ceramic selected from a group consisting of Y₃Al₅O₁₂, Y₄Al₂O₉, Y₂O₃, and a ceramic compound comprising Y₄Al₂O₉ and a solid-solution of Y₂O₃—ZrO₂, wherein the fluorinated thin film protective layer covers the additional protective layer.

19. A chamber component for a processing chamber prepared by a process comprising:
performing ion assisted deposition (IAD) to deposit a fluorinated thin film protective layer on at least one surface of the chamber component, the fluorinated thin film protective layer thin film having a thickness of less than approximately 50 microns and comprising YF₃.

20. The chamber component of claim 19, the process further comprising:
prior to depositing the fluorinated thin film protective layer on the at least one surface of the chamber component, performing a thermal spraying process to deposit an additional protective layer on the at least one surface of the body, wherein the additional protective layer is a thick film having a thickness of greater than approximately 100 microns and comprises a ceramic selected from a group consisting of Y₃Al₅O₁₂, Y₄Al₂O₉, Y₂O₃, and a ceramic compound comprising Y₄Al₂O₉ and a solid-solution of Y₂O₃—ZrO₂, wherein the fluorinated thin film protective layer covers the additional protective layer.
